(19) United States
(12) Patent Application Publication
(10) Pub. No.: US 2015/0259800 A1
(43) Pub. Date: Sep. 17, 2015

(54) PREPARING METHOD OF GRAPHENE BY USING NEAR-INFRARED AND APPARATUS THEREFOR

(71) Applicants: SNU R&DB FOUNDATION, Seoul (KR); GRAPHENE SQUARE INC., Seoul (KR); ALLIED RAY TECHNOLOGY CO., LTD., Incheon (KR)

(72) Inventors: Byung Hee Hong, Seoul (KR); Jung Hee Han, Seoul (KR); Dong Hoon Han, Incheon (KR); Won Taek Choi, Incheon (KR); Je Deok Kim, Incheon (KR)

(21) Appl. No.: 14/624,102

(22) Filed: Feb. 17, 2015

(30) Foreign Application Priority Data
Feb. 17, 2014 (KR) 10-2014-0017622
Feb. 17, 2015 (KR) 10-2015-0024120

(51) Int. Cl. C23C 16/48; C23C 16/26; C23C 16/46; C01B 31/04

(52) U.S. Cl. CPC C23C 16/483; C01B 31/0453; C23C 16/26; C23C 16/46; C23C 16/488

(57) ABSTRACT

The present disclosures described herein pertain generally to a method and an apparatus for preparing a graphene by using near-infrared light.

### CROSS-REFERENCE TO RELATED APPLICATION

This application claims the benefit under 35 USC 119(a) to Korean Patent Application No. 10-2014-0017622 filed on Feb. 17, 2014 and Korean Patent Application No. 10-2015-0024120 filed on Feb. 17, 2015, in the Korean Intellectual Property Office, the contents of all of which are incorporated herein by reference in their entirety.

### TECHNICAL FIELD

The present disclosure described herein pertains generally to a method and an apparatus for preparing a graphene by using near-infrared light.

### BACKGROUND

Low-dimensional nanomaterials consisting of carbon atoms include a fullerene, a carbon nanotube, a graphene, a graphite, and the like. That is, when carbon atoms are connected in a hexagonal shape in the form of a ball, this structure is called a zero-dimensional fullerene; when carbon atoms are rolled up one-dimensionally, this structure is called a carbon nanotube; when carbon atoms are arranged two-dimensionally in a monolayer of carbon atoms, this structure is called a graphene; and when carbon atoms are stacked three-dimensionally, this structure is called a graphite. Among these, the graphene is very stable structurally and chemically. Besides, owing to its structural characteristic of having a single-atom layer thickness and comparatively few surface defects, the graphene exhibits outstanding conductivity as an excellent conductor. For example, the graphene is capable of transferring electrons at a speed 100 times faster than that of silicon and, theoretically, the graphene is capable of allowing a flow of electric currents in an amount of about 100 times larger than that in case of copper.

As a representative method of preparing a graphene in a large area, there has been employed a chemical vapor deposition (CVD) method in which a metal catalyst is loaded into a furnace, and by heating the furnace while supplying a carbon source onto the metal catalyst, a graphene is synthesized on the metal catalyst. For example, Korean Patent Publication No. 2009-0017454 discloses a graphene hybrid material and a preparation method thereof. The aforementioned CVD method, however has drawbacks in that this method costs high and is highly time-consuming, for it takes long time to synthesize the graphene and additional utilities and additional time for cooling the heated furnace are required.

### DISCLOSURE OF THE INVENTION

### Problems to be Solved by the Invention

In view of the foregoing problems, the present disclosure provides a method of preparing a graphene by using near-infrared light, which involves supplying a reactant gas containing a carbon source to a metal catalyst; and irradiating near-infrared light to the metal catalyst to thereby generate heat from the metal catalyst itself, thus allowing a graphene to be grown on the metal catalyst. Further, the present disclosure also provides an apparatus for preparing the graphene, configured to perform the aforementioned preparing method of the graphene.

However, the problems sought to be solved by the present disclosure are not limited to the above description and other problems can be clearly understood by those skilled in the art from the following description.

### Means for Solving the Problems

In accordance with a first aspect of the present disclosure, there is provided a method of preparing a graphene using near-infrared light, comprises loading a metal catalyst in a chamber containing a transparent window; supplying a reactant gas containing a carbon source into the chamber; and irradiating near-infrared (NIR) light from the outside of the chamber to the metal catalyst through the transparent window to generate heat from the metal catalyst, thereby reacting the metal catalyst with the carbon source to grow a graphene on a surface of the metal catalyst.

In accordance with a second aspect of the present disclosure, there is provided an apparatus for preparing a graphene by using near-infrared light, comprises a chamber for accommodating a metal catalyst loaded therein; a transparent window formed on at least one side of the chamber; a reactant gas supply unit configured to supply a reactant gas containing a carbon source into the chamber; and near-infrared light source provided outside the chamber, and configured to irradiate near-infrared light into the chamber through the transparent window, to allow the metal catalyst to generate heat.

### Effect of the Invention

In accordance with the present disclosure, since the graphene is synthesized by enabling heat generation of the metal catalyst itself through the use of the near-infrared light, an energy loss to the ambient can be minimized, and, thus, the graphene can be synthesized efficiently. Further, unlike in a conventional method, since cooling of the furnace is not required after the synthesis of the graphene is completed, a cooling utility for cooling the furnace is not needed, and the time required for the synthesis of the graphene is greatly reduced. Therefore, graphene can be synthesized efficiently in a short period of time.

### BRIEF DESCRIPTION OF THE DRAWINGS

FIG. 1A and FIG. 1B are schematic diagrams illustrating an apparatus for preparing a graphene by using near-infrared light in accordance with an example of the present disclosure;

FIG. 2 shows a temperature variation depending on an irradiation time of near-infrared light in the present example of the present disclosure;

FIG. 3A and FIG. 3B show an optical micrograph and a Raman spectroscopic analysis result of a graphene prepared according to a comparative example, respectively;

FIG. 4A and FIG. 4B show an optical micrograph and a Raman spectroscopic analysis result of a graphene prepared according to a comparative example, respectively;

FIG. 5A and FIG. 5B show an optical micrograph and a Raman spectroscopic analysis result of a graphene prepared according to a comparative example, respectively;

FIG. 6A and FIG. 6B show an optical micrograph and a Raman spectroscopic analysis result of a graphene prepared according to a comparative example, respectively;

FIG. 7A and FIG. 7B show an optical micrograph and a Raman spectroscopic analysis result of a graphene prepared according to an example of the present disclosure, respectively;

FIG. 8A and FIG. 8B show an optical micrograph and a Raman spectroscopic analysis result of a graphene prepared according to an example of the present disclosure, respectively;

FIG. 9A and FIG. 9B show an optical micrograph and a Raman spectroscopic analysis result of a graphene prepared according to an example of the present disclosure, respectively;

FIG. 10A and FIG. 10B show an optical micrograph and a Raman spectroscopic analysis result of a graphene prepared according to an example of the present disclosure, respectively;

FIG. 11A and FIG. 11B show an optical micrograph and a Raman spectroscopic analysis result of a graphene prepared according to an example of the present disclosure, respectively;

FIG. 12 is an optical micrograph of graphenes prepared according to an example of the present disclosure;

FIG. 13A and FIG. 13B show an optical micrograph and a Raman spectroscopic analysis result of a graphene prepared according to an example of the present disclosure, respectively;

FIG. 14A and FIG. 14B show an optical micrograph and a Raman spectroscopic analysis result of a graphene prepared according to an example of the present disclosure, respectively;

FIG. 15A and FIG. 15B show an optical micrograph and a Raman spectroscopic analysis result of a graphene prepared according to an example of the present disclosure, respectively;

FIG. 16A and FIG. 16B show an optical micrograph and a Raman spectroscopic analysis result of a graphene prepared according to an example of the present disclosure, respectively;

FIG. 17A and FIG. 17B show an optical micrograph and a Raman spectroscopic analysis result of graphene prepared according to an example of the present disclosure, respectively;

FIG. 18A and FIG. 18B show an optical micrograph and a Raman spectroscopic analysis result of a graphene prepared according to an example of the present disclosure, respectively;

FIG. 19A to FIG. 19D show a Raman mapping data of a graphene prepared according to an example of the present disclosure;

FIG. 20 is a SEM image of a graphene prepared according to an example of the present disclosure;

FIG. 21A to FIG. 21C show optical micrographs, Raman spectroscopic analysis results, and sheet resistance graph of graphenes prepared according to an example of the present disclosure, respectively; and

FIG. 22A to FIG. 22D show a UV-IR transmittance of a graphene prepared according to an example of the present disclosure.

### DETAILED DESCRIPTION

Hereinafter, present disclosure will be described in detail so that inventive concept may be readily implemented by those skilled in the art. However, it is to be noted that the present disclosure is not limited to the illustrative embodiments and examples but can be realized in various other ways. In drawings, parts not directly relevant to the description are omitted to enhance the clarity of the drawings, and like reference numerals denote like parts through the whole document of the present disclosure.

Through the whole document of the present disclosure, the terms “connected to” or “coupled to” are used to designate a connection or coupling of one element to another element and include both a case where an element is “directly connected or coupled to” another element and a case where an element is “electronically connected or coupled to” another element via still another element.

Through the whole document of the present disclosure, the term “on” that is used to designate a position of one element with respect to another element includes both a case that the one element is adjacent to the another element and a case that any other element exists between these two elements.

Through the whole document of the present disclosure, the term “comprises or includes” and/or “comprising or including” used in the document means that one or more other components, steps, operation and/or existence or addition of elements are not excluded in addition to the described components, steps, operation and/or elements unless context dictates otherwise. The term “about or approximately” or “substantially” are intended to have meanings close to numerical values or ranges specified with an allowable error and intended to prevent accurate or absolute numerical values disclosed for understanding of the present disclosure from being illegally or unfairly used by any unconscionable third party. Through the whole document of the present disclosure, the term “step of” does not mean “step for”.

Through the whole document of the present disclosure, the term “combination of” included in Markush type description means mixture or combination of one or more components, steps, operations and/or elements selected from the group consisting of components, steps, operation and/or elements described in Markush type and thereby means that the disclosure includes one or more components, steps, operations and/or elements selected from the Markush group.

Through the whole document of the present disclosure, the expression “A and/or B” means “A or B, or A and B.”

Hereinafter, various illustrative embodiments and examples of the present disclosure will be described in detail with reference to the accompanying drawings, which form a part of the description. However, it should be noted that the illustrative embodiments, the examples and the drawings described herein are not meant to be anyway limiting.

In accordance with a first aspect of the present disclosure, there is provided a method of preparing a graphene using near-infrared light, comprises loading a metal catalyst in a chamber containing a transparent window; supplying a reactant gas containing a carbon source into the chamber; and irradiating near-infrared (NIR) light from the outside of the chamber to the metal catalyst through the transparent window to generate heat from the metal catalyst, thereby reacting the metal catalyst with the carbon source to grow a graphene on a surface of the metal catalyst.

In accordance with an illustrative embodiment of the present disclosure, the growing of the graphene on the surface of the metal catalyst may be performed by URT-CVD (Ultra Rapid Thermal Chemical Vapor Deposition), but not limited thereto.

In general, when the graphene is grown on the metal catalyst by supplying the reactant gas containing the carbon source onto the metal catalyst and heating, there has been employed a method of raising a temperature of the metal catalyst by delivering radiant heat to the metal catalyst by way of, for example, heating a furnace in which the metal catalyst is loaded. This method is, however, inefficient because a large amount of energy is lost to the ambient without being delivered to the metal catalyst. Thus, this method has a drawback in that it takes a long time ranging of from about 4 hours to about 8 hours to synthesize the graphene.

In accordance with an illustrative embodiment of the present disclosure, by irradiating the near-infrared light to the metal catalyst through the transparent window from the outside of the chamber, an internal temperature of the chamber is raised to a temperature lower than that of the metal catalyst, and, within the chamber, the temperature of the metal catalyst becomes the highest.

According to the preparing method of the graphene by using the near-infrared light of the present disclosure, since the metal catalyst to which the near-infrared light is irradiated generates heat itself, an energy loss to the ambient may hardly occur, and energy can be transferred to the metal catalyst almost completely, which is highly efficient. Further, since it only takes amount 10 minutes or less to synthesize the graphene, the time required to synthesize the graphene can be reduced and thus, the graphene can be prepared in a very short period of time.

Besides, in a conventional method of heating the furnace in which the metal catalyst is loaded or heating the metal catalyst along with the ambient utilities, an additional utility for cooling the heated furnace or ambient utilities is required. According to the preparing method of the graphene by using near-infrared light according to the present disclosure, however, since only the metal catalyst is allowed to generate heat efficiently without needing to heat the chamber or the ambient utilities, an additional cooling utility and a cooling process are not required, so that a processing time can be more reduced. Furthermore, since other materials such as high-priced graphite to be used as a susceptor within the chamber are not required for the production of the graphene, contamination within the chamber or adverse effect on a sample can be minimized.

In accordance with an illustrative embodiment of the present disclosure, in the preparing method of the graphene by using the near-infrared light according to the present disclosure, the graphene may be prepared by using a roll-to-roll system, but not limited thereto.

In accordance with an illustrative embodiment of the present disclosure, the near-infrared light may have a wavelength in the range of from about 700 nm to about 1,500 nm, but not limited thereto. By way of non-limiting example, the near-infrared light may have a wavelength ranging of from about 700 nm to about 1,500 nm, from about 900 nm to about 1,500 nm, from about 1,000 nm to about 1,500 nm, from about 1,300 nm to about 1,500 nm, from about 700 nm to about 1,300 nm, from about 700 nm to about 1,000 nm, or from about 700 nm to about 900 nm, but not limited thereto.

In accordance with an illustrative embodiment of the present disclosure, the near-infrared light may have a color temperature in the range of from about 2,200 K to about 3,500 K, but not limited thereto. By way of non-limiting example, the color temperature of the near-infrared light may be in the range of from about 2,200 K to about 3,500 K, from about 2,500 K to about 3,500 K, from about 2,800 K to about 3,500 K, from about 3,000 K to about 3,500 K, from about 3,300 K to about 3,500 K, from about 2,200 K to about 3,300 K, from about 2,200 K to about 3,000 K, from about 2,200 K to about 2,700 K, or from about 2,200 K to about 2,500 K, but not limited thereto. Desirably, the near-infrared light may have a color temperature of about 3,000 K or more. In accordance with the illustrative embodiment of the present disclosure, since the near-infrared light has the color temperature of about 3,000 K or more with high transmittance, it is possible to make the metal catalyst generate heat to about 1,000° C. or more with high speed in a short period of time when irradiating the near-infrared light to the metal catalyst through the transparent window from the outside of the chamber.

In accordance with an illustrative embodiment of the present disclosure, the metal catalyst may include a member selected from the group consisting of Ni, Co, Fe, Pt, Au, Al, Cr, Cu, Mg, Mn, Mo, Rh, Si, Ta, Ti, W, U, V, Zr, brass, bronze, stainless steel, Ge, and combinations thereof, but not limited thereto.

In accordance with an illustrative embodiment of the present disclosure, the metal catalyst may include a metal catalyst layer formed on a substrate, but not limited thereto. By way of example, the substrate may include quartz, glass, a heat resistance polymer, and/or a wafer, but not limited thereto.

In accordance with an illustrative embodiment of the present disclosure, the metal catalyst may be formed on a substrate in a roll form, but not limited thereto.

In accordance with an illustrative embodiment of the present disclosure, the carbon source may be in a gas phase or liquid phase, but not limited thereto.

In accordance with an illustrative embodiment of the present disclosure, the carbon source may include a member selected from the group consisting of carbon monoxide, carbon dioxide, methane, ethane, ethylene, ethanol, acetylene, propane, butane, butadiene, pentane, pentene, cyclopentadiene, hexane, cyclohexane, benzene, toluene, and combinations thereof, but not limited thereto.

In accordance with an illustrative embodiment of the present disclosure, one to twenty metal catalyst(s) may be loaded in the chamber, but not limited thereto. By way of non-limiting example, the number of the metal catalyst(s) loaded in the chamber may be in the range of from about 1 to about 20, from about 1 to about 15, from about 1 to about 10, from about 1 to about 5, from about 5 to about 2, from about 10 to about 20, or from about 15 to about 20, but not limited thereto.

In accordance with an illustrative embodiment of the present disclosure, the near-infrared light may be irradiated to the metal catalyst from one to six directions to grow one to six graphenes may be on the metal catalyst simultaneously, but not limited thereto.

In accordance with an illustrative embodiment of the present disclosure, the transparent window may be formed on at least one side of the chamber, but not limited thereto. By way of example, if the chamber is of a hexahedron shape, the transparent window may be formed in one to six sides of the chamber, but not limited thereto.

In accordance with an illustrative embodiment of the present disclosure, the transparent window may include quartz, sapphire or glass, but not limited to.

In accordance with a second aspect of the present disclosure, there is provided an apparatus for preparing a graphene by using near-infrared light, comprises a chamber for accommodating a metal catalyst loaded therein; a transparent window formed on at least one side of the chamber; a reactant gas supply unit configured to supply a reactant gas containing a carbon source into the chamber; and near-infrared light source provided outside the chamber, and configured to irradiate near-infrared light into the chamber through the transparent window, to allow the metal catalyst to generate heat.

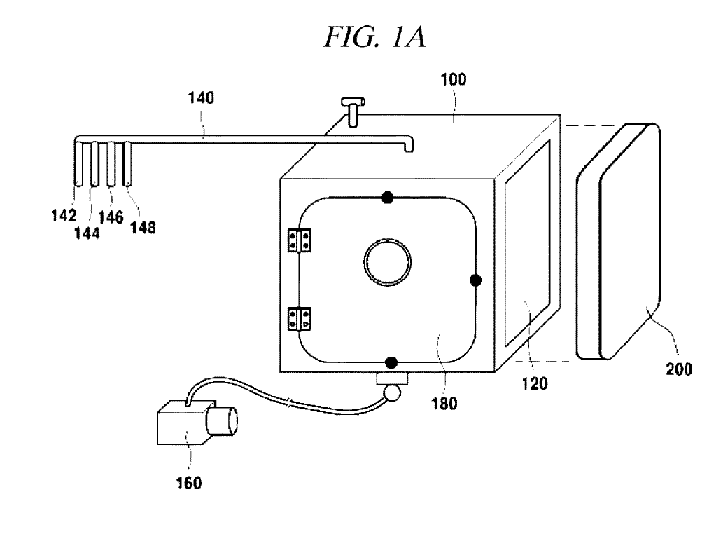

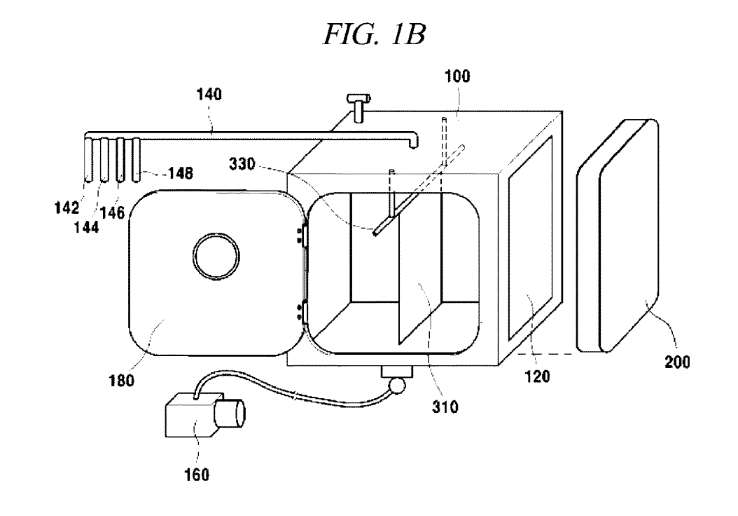

FIG. 1A and FIG. 1B are schematic diagrams illustrating a graphene preparation apparatus using near-infrared light in accordance with an example of the present disclosure. As depicted in FIG. 1A, a chamber 100 includes a transparent window 120; and a gas supply unit 140 connected to the chamber. Further, a vacuum pump 160 configured to adjust an internal pressure of the chamber is also connected to the chamber, and the chamber 100 is equipped with a door 180 through which a metal catalyst is loaded into the chamber. The gas supply unit 140 is connected with a carbon source injector 142, a hydrogen gas injector 144, an argon gas injector 146 and a backup gas injector 148. Further, near-infrared light source 200 configured to irradiate near-infrared light to the inside of the chamber 100 through the transparent window 120 is provided outside the chamber 100. As can be seen from FIG. 1B, a metal catalyst 310 is loaded in the chamber, and the metal catalyst 310 is immobilized by a metal catalyst supporting unit 330.

If the near-infrared light source 200 is disposed within the chamber 100, a precise electric contact unit is required because the near-infrared light source 200 should be usable in a vacuum environment. If, however, the near-infrared light source 200 is disposed outside the chamber 100 according to the illustrative embodiment of the present disclosure, the near-infrared light source 200 only needs to have an electric contact unit capable of being used under a general atmospheric condition, and, thus, the produce thereof may be easy.

In accordance with an illustrative embodiment of the present disclosure, the transparent window 120 is formed at one side of the chamber 100 to have a thickness that allows the transparent window to have enough strength to endure a vacuum pressure within the chamber 100. By way of non-limiting example, the thickness of the transparent window 120 may be proportional to the area of the transparent window 120. In accordance with an illustrative embodiment of the present disclosure, the transparent window 120 may include quartz, sapphire, or glass, but not limited thereto.

In accordance with an illustrative embodiment of the present disclosure, the near-infrared light source 200 may include near-infrared module, but not limited thereto. For example, the near-infrared module may include one or more near-infrared light sources, specifically, from about 1 to about 100 near-infrared light sources, but not limited thereto. For instance, the near-infrared module may include from about 1 to about 100, from about 10 to about 100, from about 30 to about 100, from about 50 to about 100, from about 70 to about 100, from about 1 to about 70, from about 1 to about 50, from about 1 to about 30, or from about 1 to about 10 near-infrared light sources, but not limited thereto.

By way of example, the near-infrared light source 200 may include near-infrared lamp, but not limited thereto. For instance, the near-infrared light source 200 may include one or more near-infrared lamps, but not limited thereto. By way of example, in case that the near-infrared light source includes one or more near-infrared lamps, reflecting plates may be additionally provided between the near-infrared lamps to reduce interference between the lamps that might be caused by heat generation of the near-infrared lamps.

In accordance with an illustrative embodiment of the present disclosure, the near-infrared lamp may include, though not illustrated, a window surrounding the near-infrared lamp to protect it, but not limited thereto. Besides, since the near-infrared light source 200 including the near-infrared lamp is disposed outside the chamber 100, there is no likelihood that the near-infrared lamp, the window and the reflecting plate included in the near-infrared light source 200 may be contaminated. Therefore, stable control of the near-infrared light source 200 can be implemented without suffering fluctuation in performance, and stable durability of the near-infrared light source 200 can also be achieved.

In accordance with an illustrative embodiment of the present disclosure, as the near-infrared light source 200 is provided at the outside of the chamber 100, it can be fabricated easily and, even if the near-infrared light source is out of order, repair and maintenance thereof can be performed easily, and an inflow of contaminants through a heating element can be avoided. In accordance with an illustrative embodiment of the present disclosure, since the near-infrared light source is provided at the outside of the chamber 100, maintenance of the near-infrared light source 200 can be performed irrelevantly to conditions within the chamber 100 such as vacuum.

In accordance with an illustrative embodiment of the present disclosure, the near-infrared module may include near-infrared heating module, but not limited thereto.

In accordance with an illustrative embodiment of the present disclosure, the near-infrared heating module may have an energy output of about 800 kW/m² or more, but not limited thereto. In accordance with an illustrative embodiment of the present disclosure, as the near-infrared heating module has the energy output of about 800 kW/m² or more, it is possible to generate heat from the metal catalyst at a temperature equal to or higher than about 3,000 K at a high speed from the outside of the chamber.

A method of synthesizing a graphene through chemical vapor deposition by using an energy output equal to or higher than about 800 kW/m² and an energy source of about 3,000 K or more may be defined as URT-CVD (Ultra Rapid Thermal Chemical Vapor Deposition). The URT-CVD has an advantage, as compared to a conventional synthesis method using RT-CVD (Rapid Thermal Chemical Vapor Deposition), in that a temperature of the substrate can be raised in a shorter period of time. Particularly, in case that the near-infrared light source 200 is provided at the outside of the chamber 100, the energy source from the light source may have difficulty in passing through inside of the chamber 100 in a vacuum state. In such a case, by using the URT-DVD method having a higher energy source output capability than that of the conventional RT-CVD method, the energy source can be allowed to pass through the vacuum state efficiently.

In accordance with an illustrative embodiment of the present disclosure, the near-infrared light source may be configured to irradiate near-infrared light of a wavelength in the range of from about 700 nm to about 1,500 nm, but not limited thereto. For example, the near-infrared light may have a wavelength in the range of from about 700 nm to about 1,500 nm, but not limited thereto. By way of non-limiting example, the near-infrared light may have a wavelength in the range of from about 700 nm to about 1,500 nm, from about 900 nm to about 1,500 nm, from about 1,000 nm to about 1,500 nm, from about 1,300 nm to about 1500 nm, from about 700 nm to about 1,300 nm, from about 700 nm to about 1,000 nm, or from about 700 nm to about 900 nm, but not limited thereto.

In accordance with an illustrative embodiment of the present disclosure, the number of the near-infrared light source 200 may be one or more, but not limited thereto. By way of example, the number of the near-infrared light source 200 may be in the range of from about 1 to about 100, from about 10 to about 100, from about 30 to about 100, from about 50 to about 100, from about 70 to about 100, from about 1 to about 70, from about 1 to about 50, from about 1 to about 30, or from about 1 to about 10, but not limited thereto.

In accordance with an illustrative embodiment of the present disclosure, the metal catalyst 310 may include a metal catalyst layer formed on a substrate, but not limited thereto.

In accordance with an illustrative embodiment of the present disclosure, the metal catalyst 310 may be formed on a substrate in a roll form, but not limited thereto.

In accordance with an illustrative embodiment of the present disclosure, the apparatus may further comprise a metal catalyst supporting unit 330, provided in the chamber 100 and configured to support the metal catalyst 310, but not limited thereto. For example, the metal catalyst supporting unit may be connected to at least a part of the metal catalyst to thereby hold the metal catalyst within the chamber, but not limited thereto. By way of example, the metal catalyst supporting unit may be implemented by, but not limited to, a jig. For instance, the metal catalyst supporting unit may further include a temperature measurement unit, but not limited thereto.

Below, examples of the present disclosure will be described in further detail. However, the following examples are intended to facilitate understanding of the present disclosure and therefore are not intended to limit its scope.

### EXAMPLES

Synthesis of Graphene Using Near-Infrared Light

A copper foil was inserted into the chamber. After creating a low-pressure atmosphere (about 5.0 Torr) within the chamber, methane (150 sscm) as a carbon source and hydrogen (15 sscm) were injected. By irradiating near-infrared light to the copper foil through the transparent window of the chamber, heat was generated from the copper foil and a CVD graphene was synthesized on the copper foil.

The near-infrared light was irradiated to the copper foil by using a 4 kw near-infrared lamp configured to generate near-infrared light having a wavelength in the range of from 700 nm to 1,500 nm, and experiments were conducted while varying an irradiation time and an irradiation intensity. The near-infrared light irradiation intensity was expressed as a percentage (%), and a case of using twelve 4 kw near-infrared lamps was set as a reference of 100%.

After graphene was synthesized, an argon gas as an inert gas was injected into the chamber in order to balance an internal pressure and an external pressure of the chamber. When the internal pressure of the chamber becomes equal to an atmospheric pressure, the chamber was opened, and samples were taken out and analyzed.

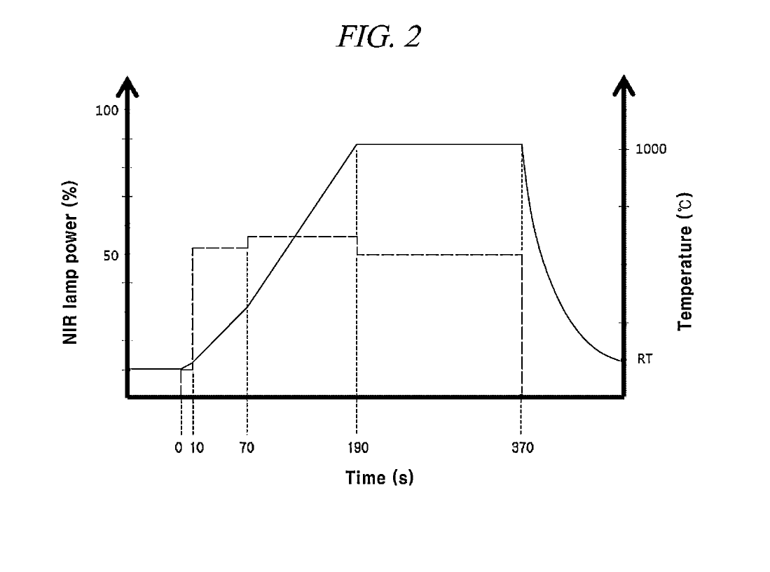

FIG. 2 shows a temperature variation depending on the near-infrared light irradiation time in accordance with the present example. As can be seen from FIG. 2, in the synthesis of graphene through the use of the near-infrared light in accordance with the present example, a temperature could be increased in a short time by irradiating the near-infrared light, thus enabling to synthesize the graphene efficiently.

Conditions for the synthesis of the graphene through the use of the near-infrared light in accordance with the present example are specified in the following Table 1.

TABLE 1

| | Copper | Copper | Copper | Copper | Copper | Copper | Copper | Copper | Copper |
|---|---|---|---|---|---|---|---|---|---|
| | Foil | Foil | Foil | Foil | Foil | Foil | Foil | Foil | Foil |
| | (1) | (2) | (3) | (4) | (5) | (6) | (7) | (8) | (9) |
| Intensity | 50 | 50→65 | 50→65 | 50→65 | 50→65 | 50→60 | 50→60 | 50→55 | 50→55 |
| (Power, %) | | | | | | | | →48 | →49 |
| Irradiation | 50%-90 | 15%-10 | 15%-10 | 15%-10 | 15%-10 | 15%-10 | 15%-10 | 10%-10 | 10%-10 |
| Time | | 50%-180 | 50%-180 | 50%-180 | 50%-180 | 50%-180 | 50%-180 | 50%-60 | 50%-60 |
| (sec) | | 65%-70 | 65%-120 | 65%-20 | 65%-100 | 65%-8 | 65%-15 | 55%-120 | 55%-120 |
| | | | | | | | | 48%-180 | 49%-120 |
| Pressure | 5.1 | 5.0 | 5.0 | 5.2 | 5.1 | 5.0 | 5.0 | 1.3 | 1.8 |
| (Torr) | | | | | | | | | |
| Methane | 150 | 150 | 150 | 150 | 150 | 150 | 150 | 120 | 170 |
| (sccm) | | | | | | | | | |
| Hydrogen | 15 | 15 | 15 | 15 | 15 | 15 | 15 | 10 | 10 |
| (sccm) | | | | | | | | | |

### Comparative Example

Synthesis of Graphene Using Graphite Layer as Heat Transfer Medium

As a comparative example, in the synthesis of a graphene using CVD, a graphite layer having a thickness of 3 μm was used as an intermediate material. The graphite layer was first heated by using near-infrared light. As heat was transferred from the graphite layer to the metal catalyst, the metal catalyst was heated and a graphene was formed on the metal catalyst. An internal pressure of a chamber was maintained in the range of from about 3.1 Torr to about 6.1 Torr. The graphene was synthesized by injecting methane (150 sscm) as a carbon source and hydrogen (15 sscm to 30 sccm).

As the comparative example, conditions for the synthesis of the graphene using the graphite layer are specified in the following Table 2.

TABLE 2

| | | Copper foil I | Copper foil II |
|---|---|---|---|
| Intensity (power, %) | | 50 → 65 | 10 → 65 |
| Irradiation time (sec) | | 50%-180 | 50%-490 |
| | | 65%-120 | 65%-30 |
| Pressure (Torr) | | 5.1 | 3.5 |
| Gas injection amount | Methane | 150 | 150 |
| (sccm) | Hydrogen | 15 | 15 |

| | |
|---|---|
| Remarks | Graphite was used as susceptor |

Result of Graphene Synthesis Using Graphite Layer

In the present comparative example, graphite was used as a susceptor for growing graphene by transferring heat to the metal catalyst, and a copper foil (Nippon Mining, 30 μm) was used as the metal catalyst for the growth of the graphene. The copper foil was prepared by coating an oxidation barrier on a surface of a copper foil which was generally used for the synthesis of graphene. Referring to Table 2, in an experiment of copper foil I, the aforementioned copper foil was used without being treated at all. Meanwhile, in an experiment of copper foil II, the aforementioned copper foil was used after the oxidation barrier was etched and removed by being heat-treated under a hydrogen (H₂) atmosphere at a temperature 500° C. or more for 30 minutes.

As a result of synthesizing the graphene on the respective metal catalysts by using the graphite layer as the intermediate material, it was found out that, although the graphene was synthesized in both cases, as the synthesis of the graphene was repeated in the same chamber or as the heating time increased, the graphite was diffused within the chamber, resulting in contamination. Due to such contamination, there occurred a problem in a subsequent graphene synthesis which is performed additionally. Further, it was also observed that the carbon was coated on a quartz plate forming a transparent window of the chamber, resulting in a decrease of the energy of an irradiated light beam and an adverse effect on the synthesized graphene.

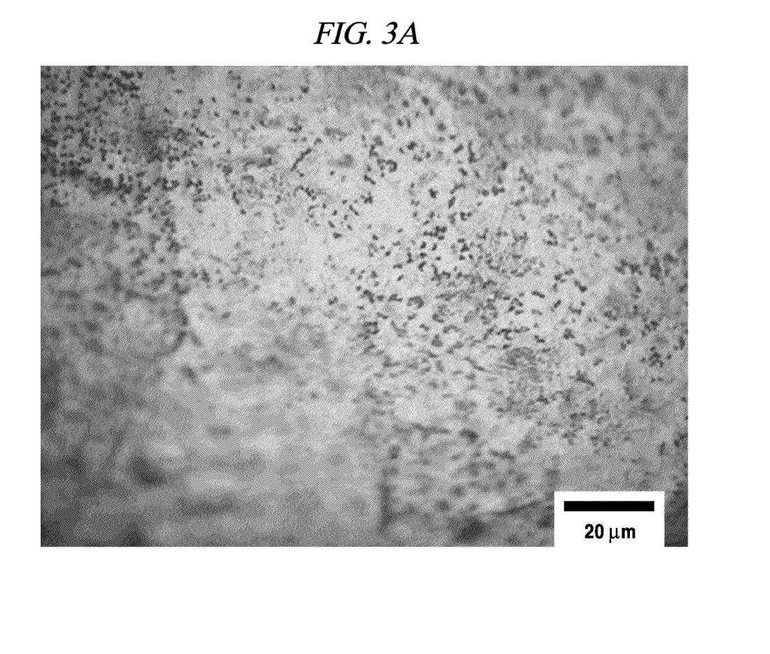

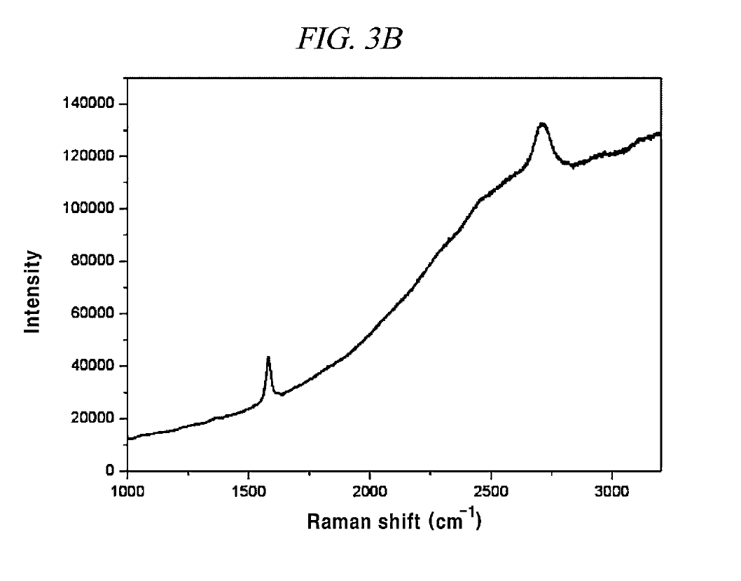

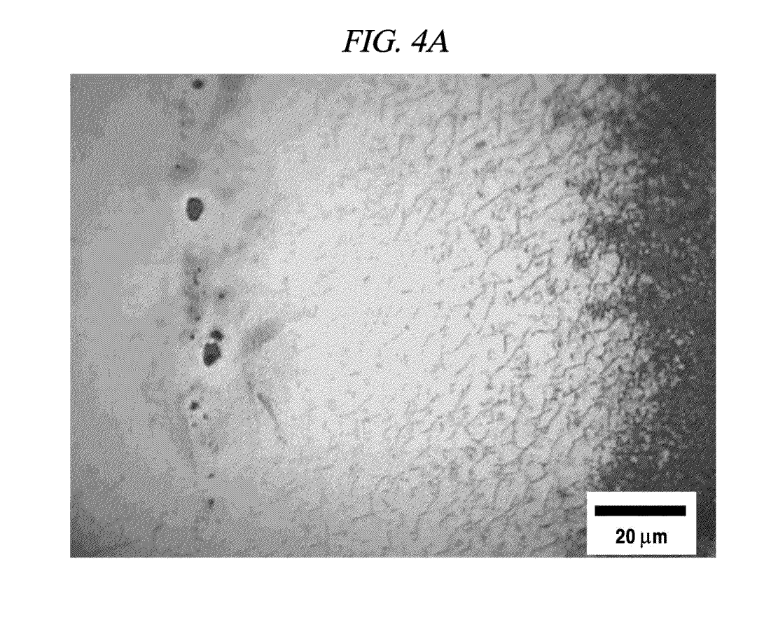

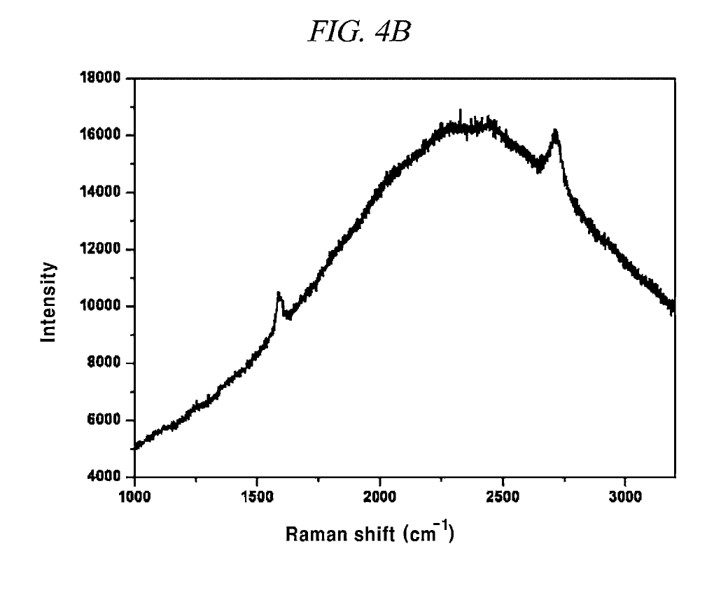

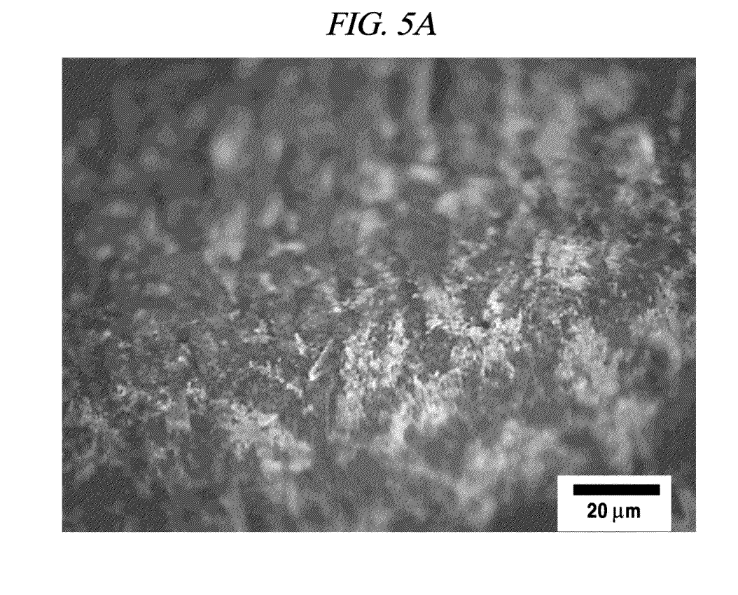

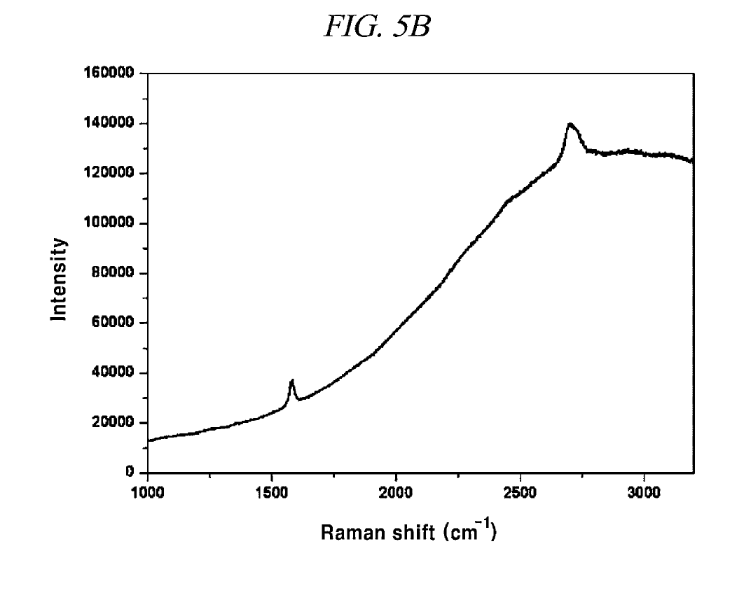

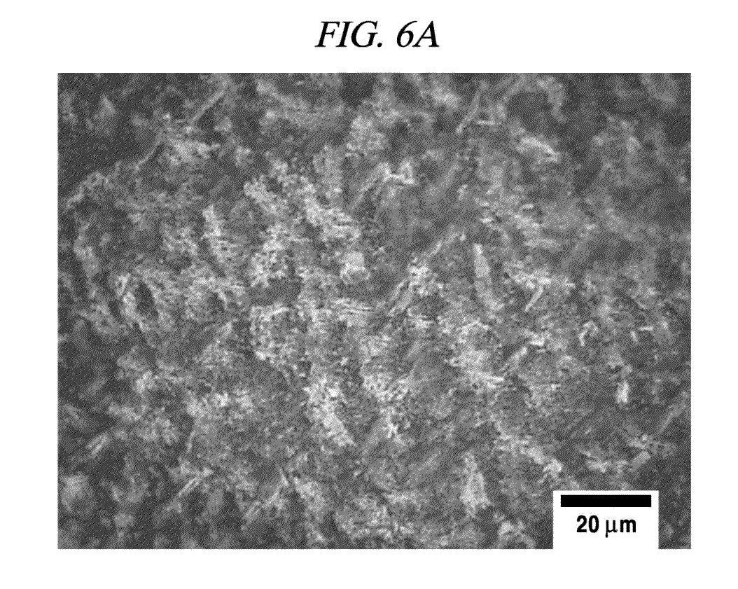

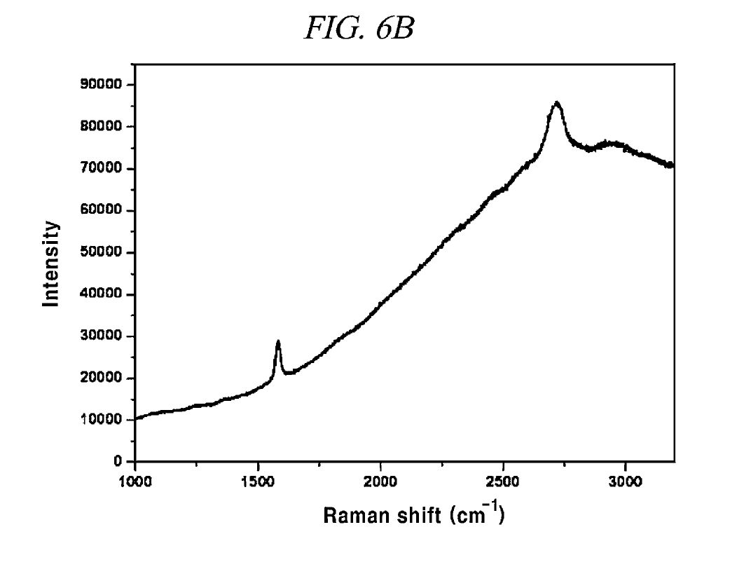

FIG. 3A, FIG. 4A, FIG. 5A and FIG. 6A are optical micrographs of graphenes synthesized by using the graphite layer as the intermediate material, which were captured using a CCD camera. FIG. 3B, FIG. 4B, FIG. 5B and FIG. 6B provide Raman spectroscopic analysis results of the graphenes synthesized by using the graphite layer as the intermediate material. Specifically, FIG. 3A, FIG. 3B, FIG. 4A and FIG. 4B show the results of synthesizing the graphenes by using the copper foil II with an irradiation intensity of 65% for 30 seconds, whereas FIG. 5A, FIG. 5B, FIG. 6A and FIG. 6B show the results of synthesizing the graphenes by using the copper foil I with an irradiation intensity of 65% for 120 seconds.

G-peaks and 2D-peaks were observed on all of the Raman spectrographs, which meant that the graphene was synthesized in all cases.

Result of Graphene Synthesis Using Near-Infrared Light

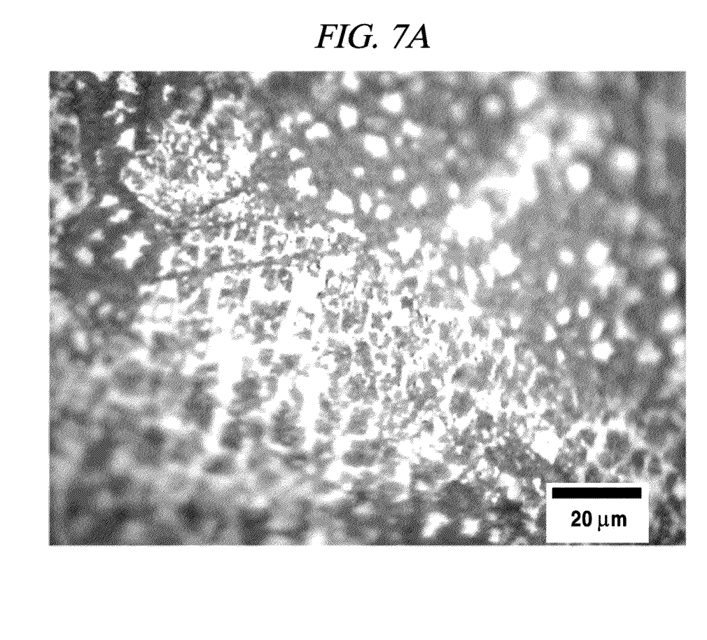

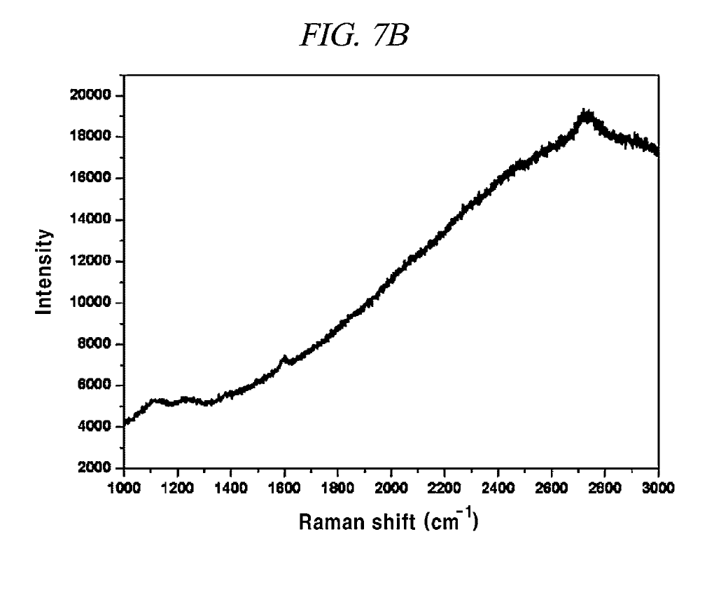

FIG. 7A and FIG. 7B show an optical micrograph and a Raman spectrographic analysis result of a graphene synthesized under the condition of copper foil (3). Specifically, the figures show an analysis result of a sample for which the experiment was ended after an irradiation time of near-infrared light passed a certain point of inflection (a time point of synthesis) in the synthesis of the graphene through chemical vapor deposition using the near-infrared light. As can be seen from the micrograph of FIG. 7A, a surface of a base material (copper foil) was not good, and as can be seen from the graph of FIG. 7B, a D-peak corresponding to impurities was found to be larger than a G-peak. That is, it can be expected that if the irradiation time of the near-infrared light is lengthened excessively, it may have an adverse effect on the graphene synthesis.

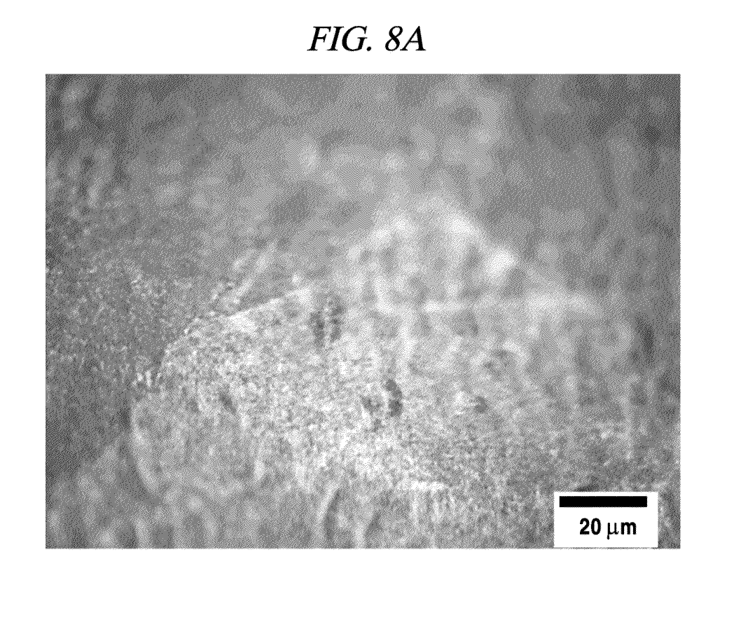

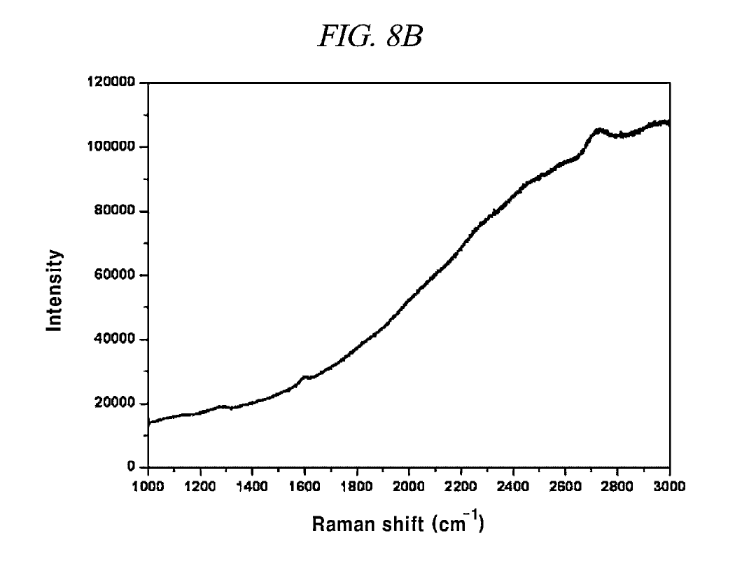

FIG. 8A and FIG. 8B show an optical micrograph and a Raman spectroscopic analysis result of a graphene synthesized under the condition of copper foil (4). Specifically, the figures show an analysis result of a sample for which the experiment was ended before an irradiation time of near-infrared light passed a certain point of inflection (a time point of synthesis) in the synthesis of the graphene through chemical vapor deposition using the near-infrared light. As can be seen from the micrograph of FIG. 8A, although there was found no problem in a surface of a base material (copper foil), a ratio of a D-peak to a G-peak was similar to that of the graphene synthesized under the condition of copper foil (3), as can be seen from the graph of FIG. 8B. This result indicates that the quality of the synthesized graphene was not good.

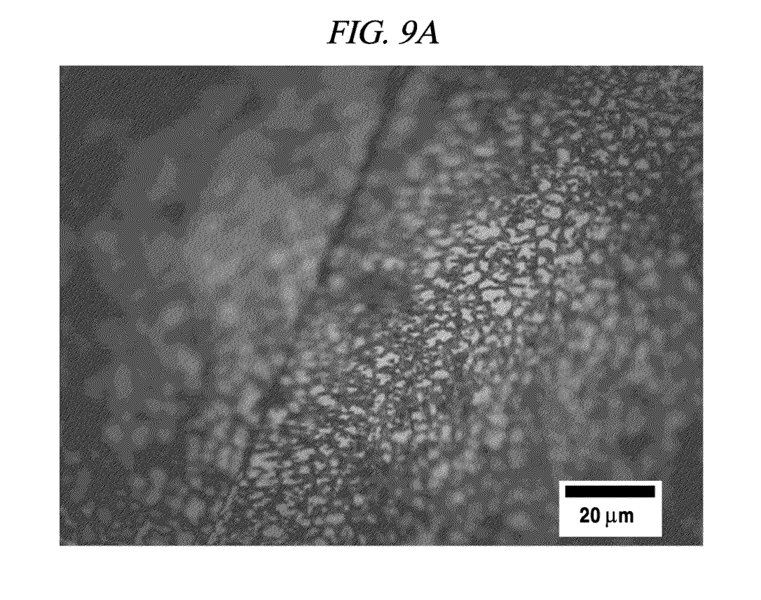

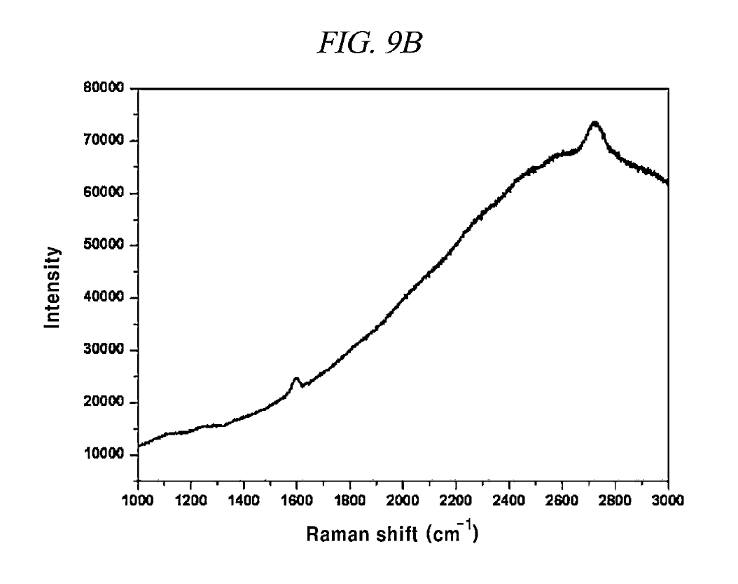

FIG. 9A and FIG. 9B show an optical micrograph and a Raman spectroscopic analysis result of a graphene synthesized under the condition of copper foil (5), respectively. Specifically, the figures show an analysis result of a sample for which the experiment was ended at the moment an irradiation time of near-infrared light reached a certain point of inflection (a time point of synthesis) in the synthesis of the graphene through chemical vapor deposition using the near-infrared light.

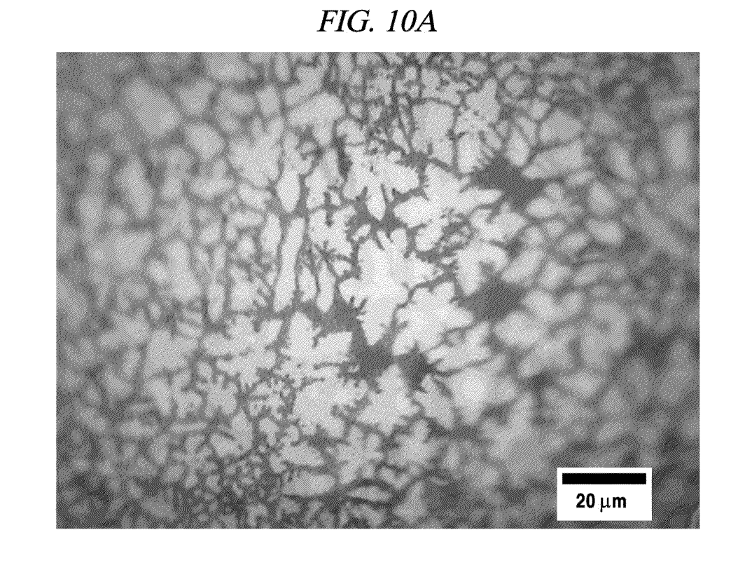

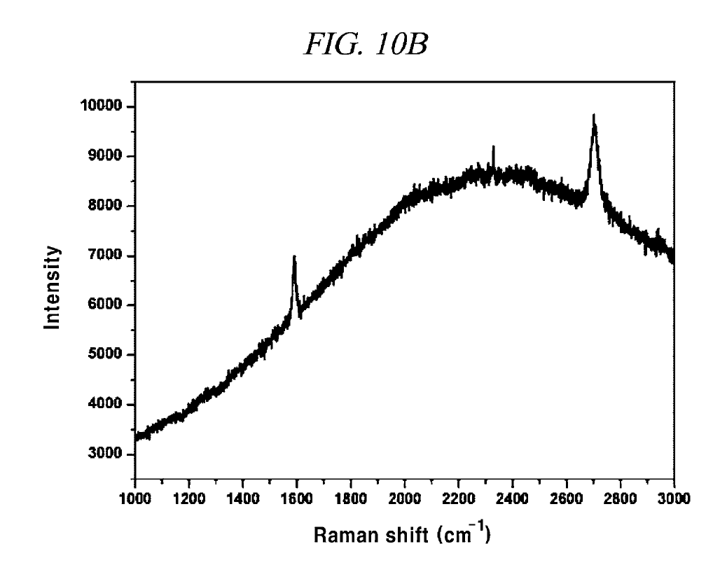

FIG. 10A and FIG. 10G show an optical micrograph and a Raman spectroscopic analysis result of a graphene synthesized under the condition of copper foil (5). Specifically, the figures show an analysis result of a sample for which the experiment was ended at the moment an irradiation time of near-infrared light reached a certain point of inflection (a time point of synthesis) in the synthesis of the graphene through chemical vapor deposition using the near-infrared light. According to the image shown in FIG. 10A, a graphene domain size was expected to be about 20 μm, which indicated that the graphene had a comparatively large area. Further, as can be seen from the graph of FIG. 10B, a D-peak was minimized, and widths of a G-peak and a 2D-peak were narrow and distinct. Thus, the result shows that the graphene at the corresponding position was a high-quality monolayer graphene.

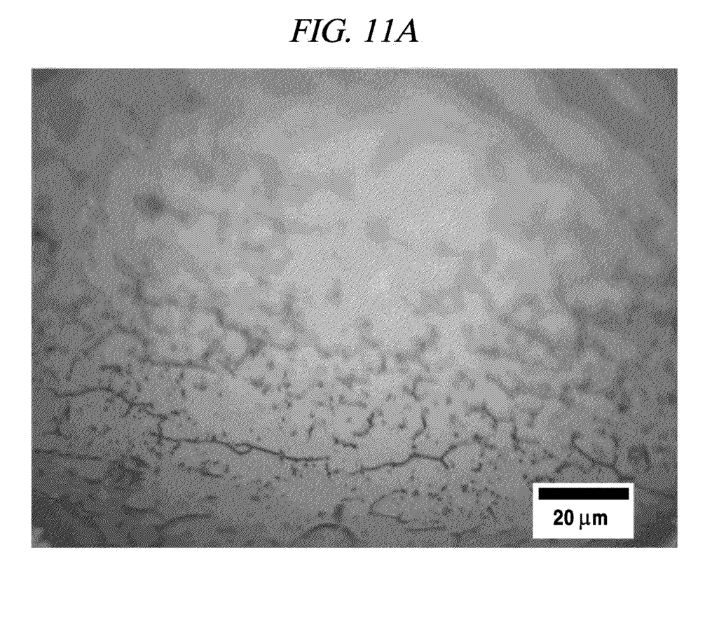

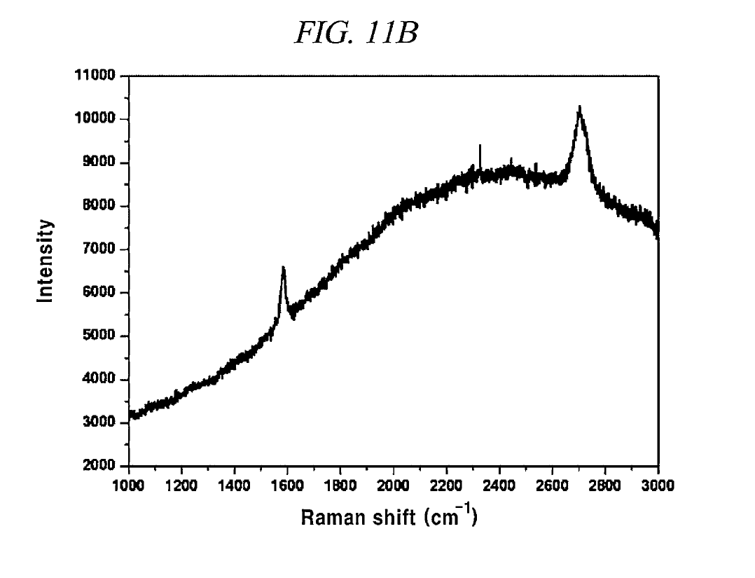

FIG. 11A and FIG. 11B show an optical micrograph and a Raman spectroscopic analysis result of a graphene synthesized under the condition of copper foil (5). Specifically, the figures show an analysis result of a sample for which the experiment was ended at the moment an irradiation time of near-infrared light reached a certain point of inflection (a time point of synthesis) in the synthesis of the graphene through chemical vapor deposition using the near-infrared light. As can be seen from the image of FIG. 11A, a graphene domain size was found to be expanded, and adjacent graphene domains were mutually offset. Further, as can be seen from the graph of FIG. 11B, a D-peak was minimized, and an intensity of a 2D-peak was larger than an intensity of a G-peak. Thus, the result shows that the synthesized graphene was a high-quality monolayer graphene.

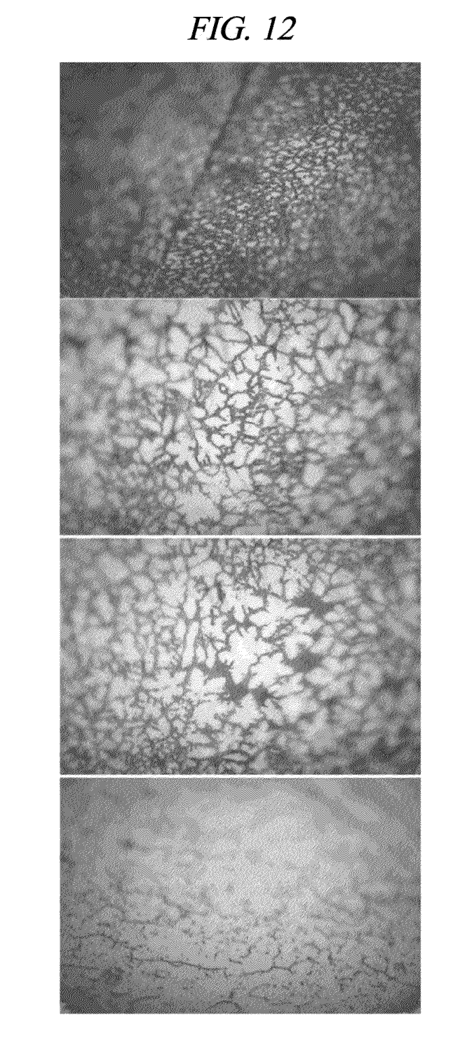

FIG. 12 shows optical micrographs of a graphene synthesized under the condition of copper foil (5).

As can be seen from FIG. 12, although the graphene was not yet completely synthesized uniformly, there was observed a process whereby graphene film was synthesized gradually. Thus, it was expected that high-quality graphene could be synthesized under the optimum reaction conditions. Specifically, as it goes from the topmost image toward the bottommost image as can be seen from FIG. 12, it could be observed that as the copper foil received the energy of the near-infrared light irradiated thereto, the synthesis of the graphene progressed and the graphene domain size was expanded.

Analysis of characteristics of graphene transferred after synthesized by using near-infrared light

In this present example, a graphene synthesized by using near-infrared light was transferred onto SiO₂, and an optical micrograph using a CCD camera and a Raman analysis graph were acquired.

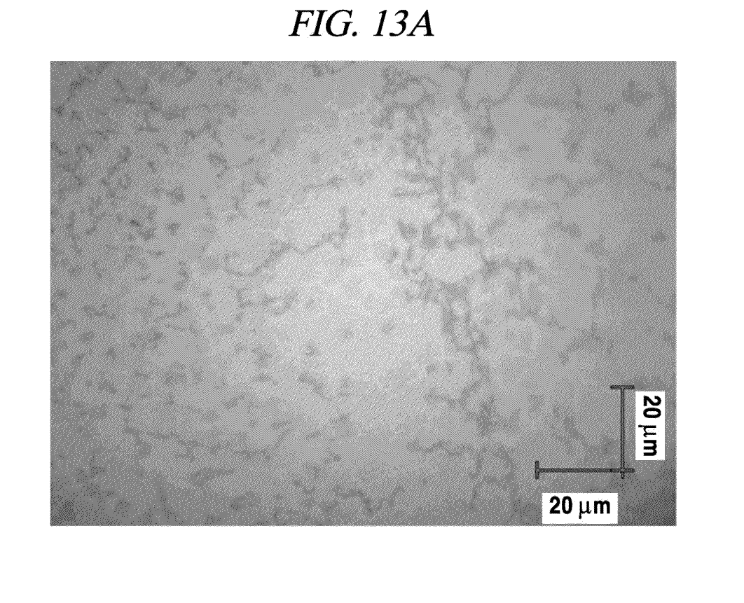

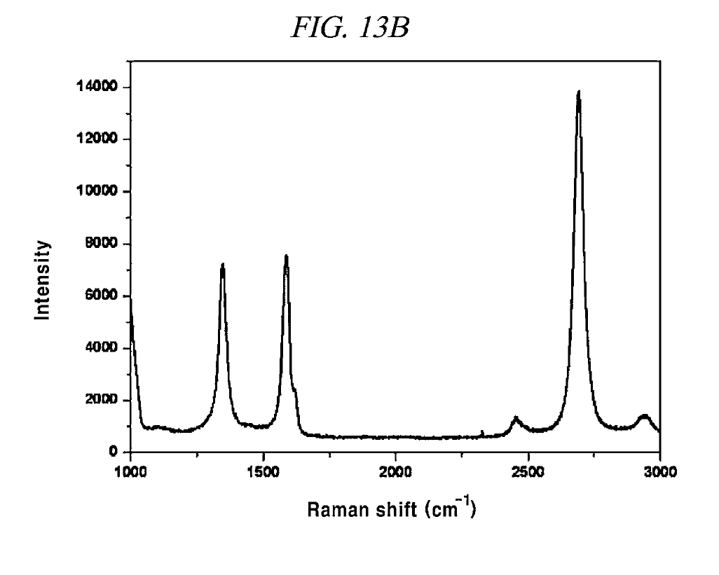

FIG. 13A and FIG. 13B provide an optical micrograph (×500) and a Raman spectrograph of a graphene synthesized under the condition of copper foil (5). As can be seen from FIG. 13B, the synthesis of the graphene was not optimized partially, and a D-peak was found to be of a high value. In view of a ratio of a 2D-peak to a G-peak, however, it was found that the synthesized graphene was a monolayer graphene.

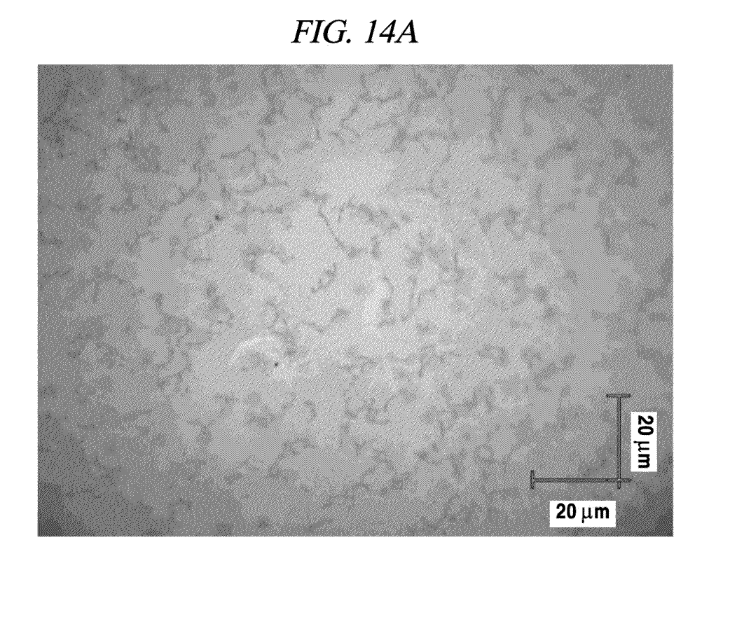

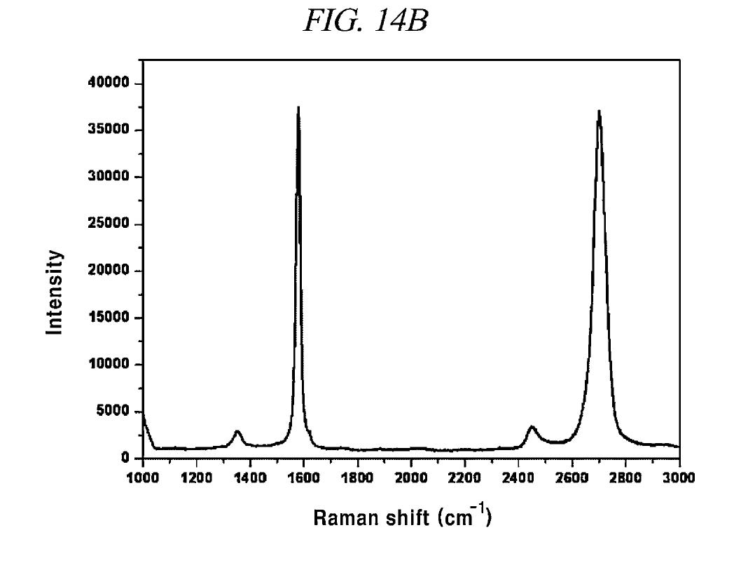

FIG. 14A and FIG. 14B provide an optical micrograph (×500) and a Raman spectrograph of a graphene synthesized under the condition of copper foil (5). According to FIG. 14A, it was observed that there was a color contrast depending on variation of the number of layer of the synthesized graphene. Although a color contrast was observed locally, it was expected that synthesis of complete monolayer graphene could be achieved if the conditions for the synthesis were more optimized. As shown in FIG. 14B, in consideration of the transfer process, a relatively low D-peak was observed, which implied that the quality of the graphene was high. Further, in view of a ratio of a 2D-peak to a G-peak, it was found that about two-layered or three-layered graphene was formed.

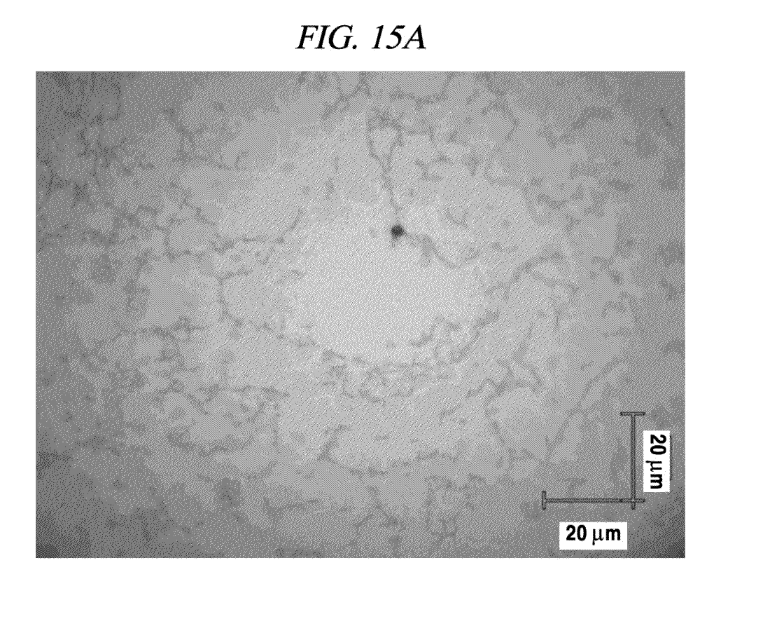

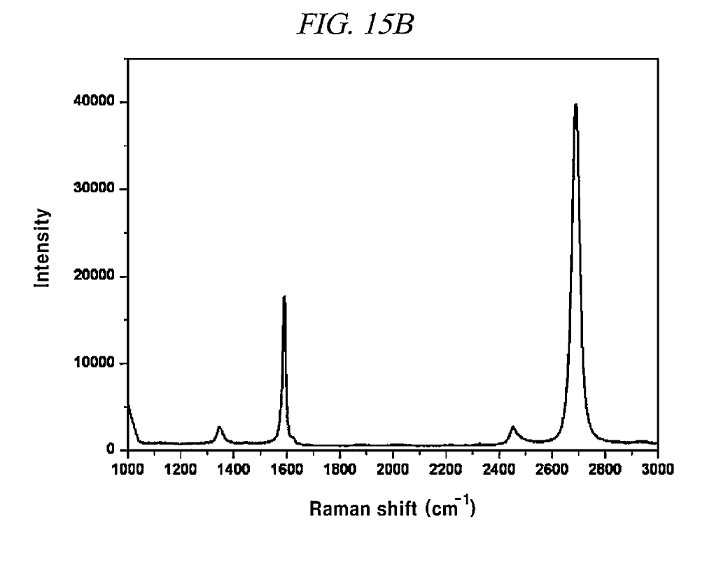

FIG. 15A and FIG. 15B provide an optical micrograph (×500) and a Raman analysis graph of a graphene synthesized under the conditions of copper foil (5). According to FIG. 15A, there was observed an image of clearly transferred graphene with insignificant color contrast depending on variation of the number of layer of the synthesized graphene. As shown in FIG. 15B, in consideration of the transfer process, a relatively low D-peak was observed, which implied that the quality of the graphene was high. Further, in view of a ratio of a 2D-peak to a G-peak, it was found that a monolayer graphene was formed.

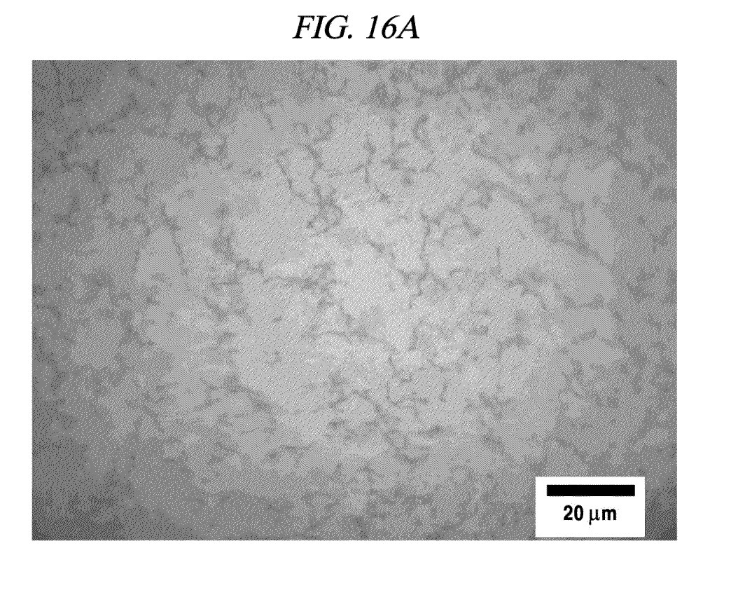

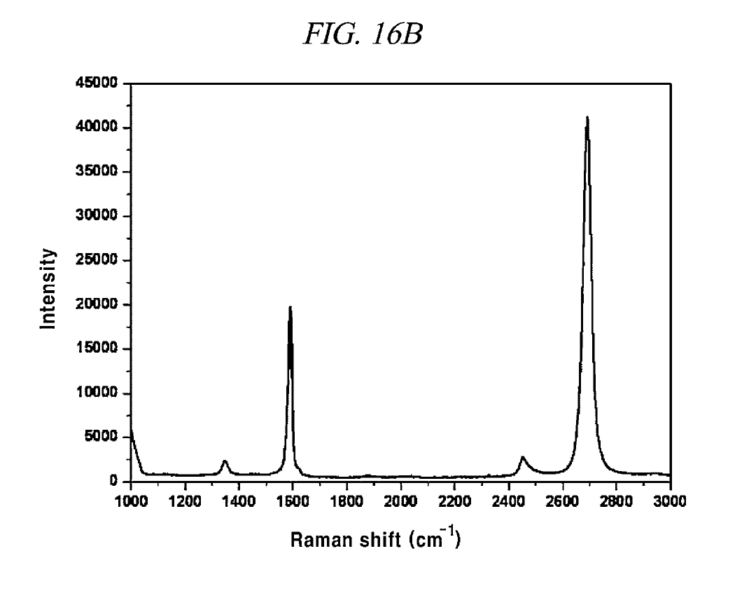

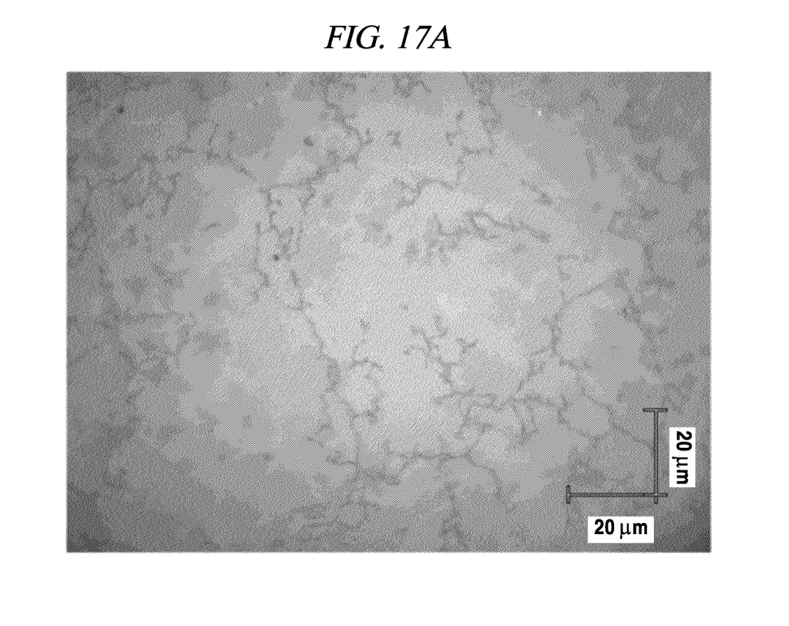

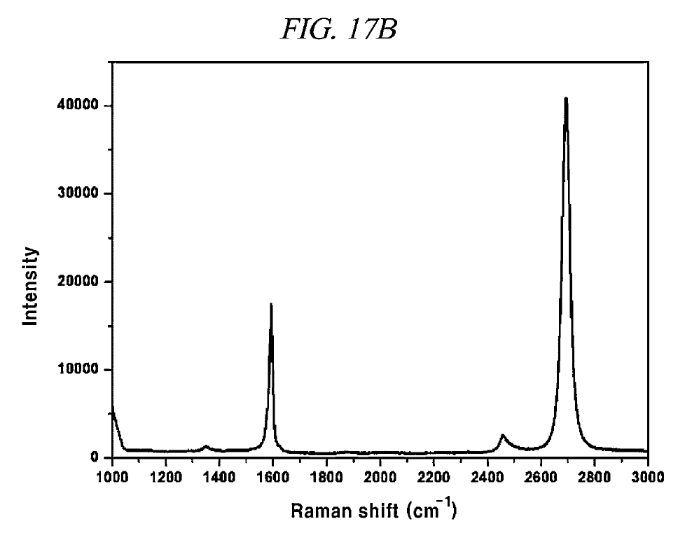

FIG. 16A, FIG. 16B, FIG. 17A and FIG. 17b show optical micrographs and Raman analysis graphs of graphenes synthesized under the condition of copper foil (5). Alike in FIG. 15A and FIG. 15B, it was found out that high-quality monolayer graphenes were formed.

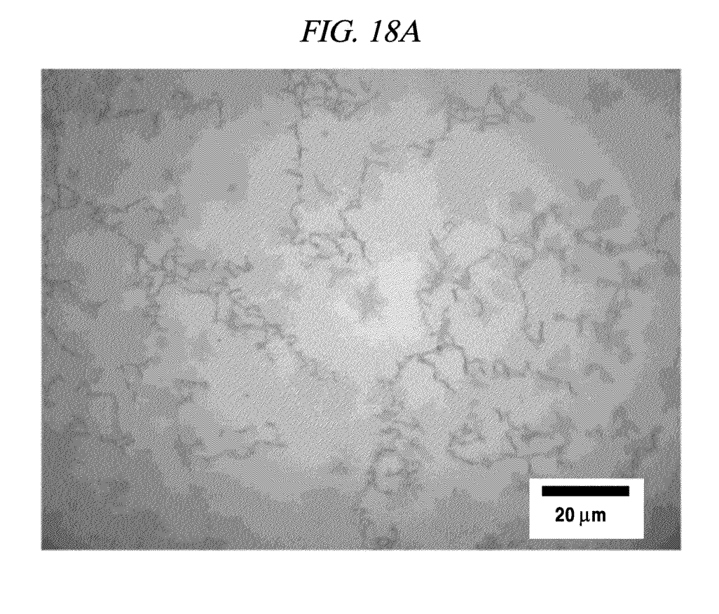

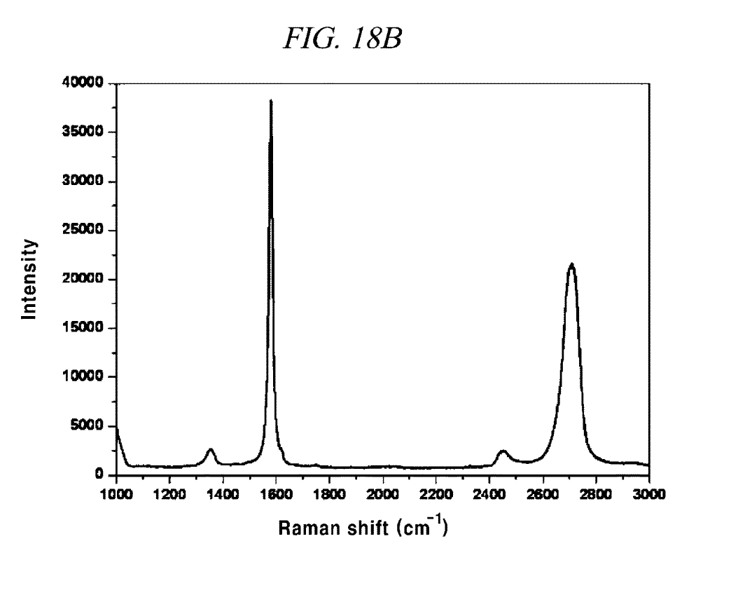

FIG. 18A and FIG. 18B provide an optical micrograph (×500) and a Raman analysis graph of a graphene synthesized under the condition of copper foil (5). A Raman analysis result of a central dark portion observed in FIG. 18A is shown in FIG. 18B. As depicted in FIG. 18B, although a relative low D-peak appeared, a ratio of a 2D-peak to a G-peak was high, and the width of the 2D-peak was relatively large, which implied that multi-layer graphene was formed.

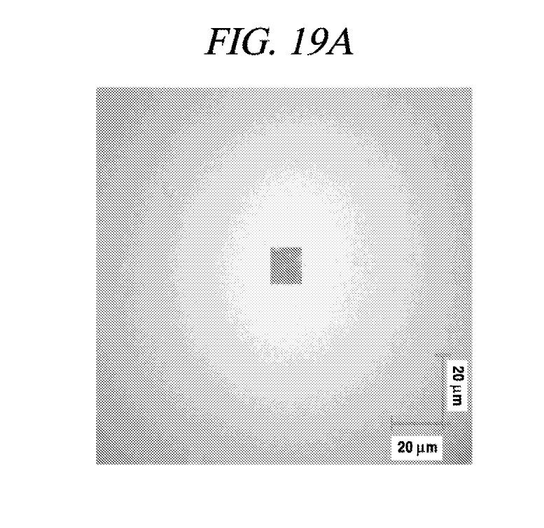

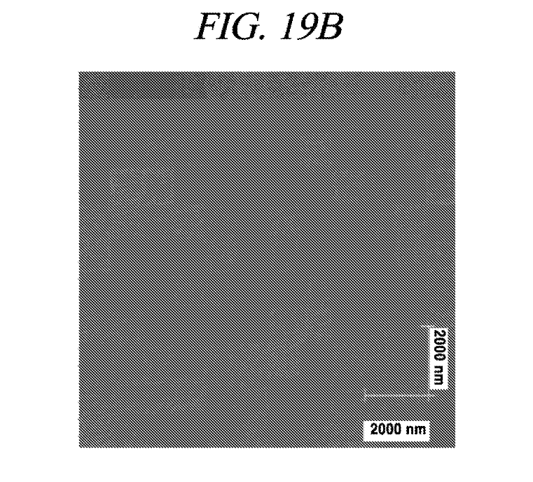

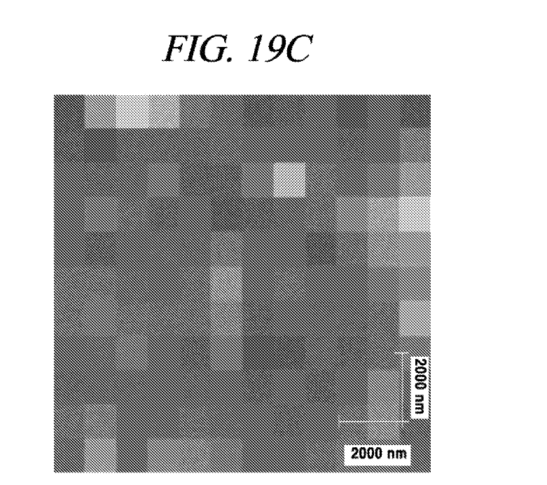

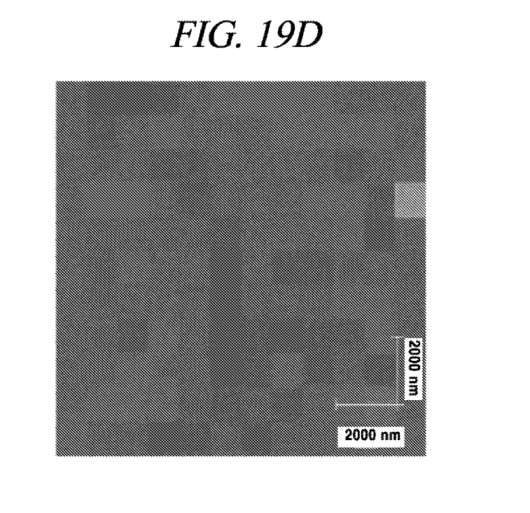

FIGS. 19A to 19D provide Raman mapping data acquired by transferring a large-size graphene, which was prepared by using near-infrared light under the conditions of copper foil (8) and copper foil (9), on to a SiO₂ wafer. FIG. 19A shows an optical micrograph of the graphene transferred onto the SiO₂ wafer in the present example; FIG. 19B, a D-peak; FIG. 19C, a G-peak; and FIG. 19D, a 2D-peak. In view of a insignificant contrast between the D-peak and the G-peak of the graphene having a unit area of 20 μm×20 μm, it was proved that the graphene was synthesized uniformly over the entire area. Also, considering the fact that there was hardly different in 2D-peak density, it was believed that the graphene exhibited high uniformity within the measurement area.

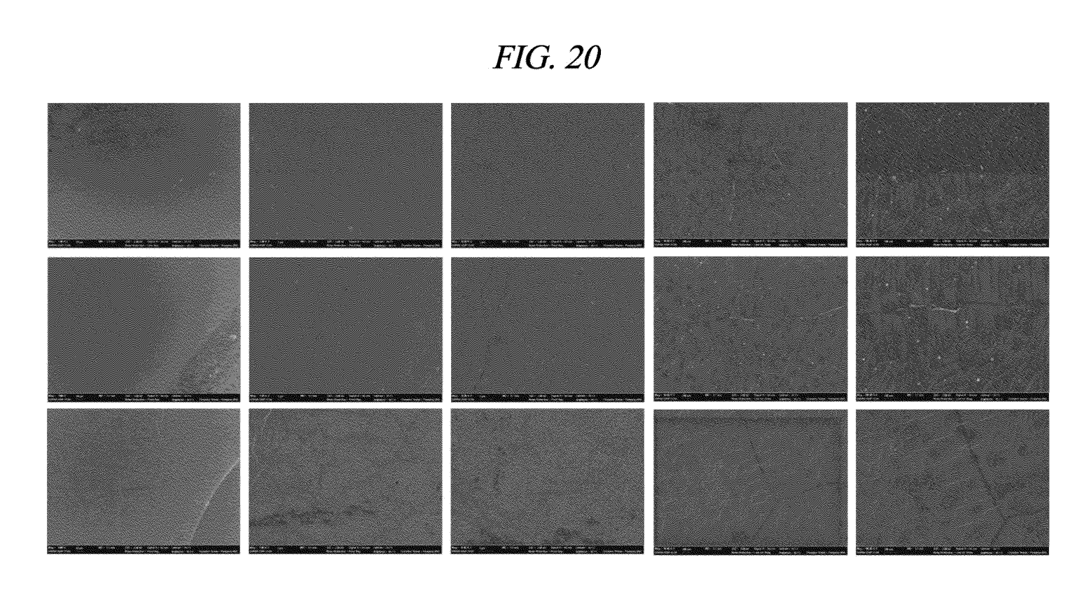

FIG. 20 depicts SEM images of graphenes synthesized on copper foils by using near-infrared light under the conditions of copper foil (8) and copper foil (9) in accordance with the present example. As it goes from the left images to the right images, the SEM images observed by 1,000 magnification, 5,000 magnification, 10,000 magnification, 50,000 magnification, 100,000 magnification.

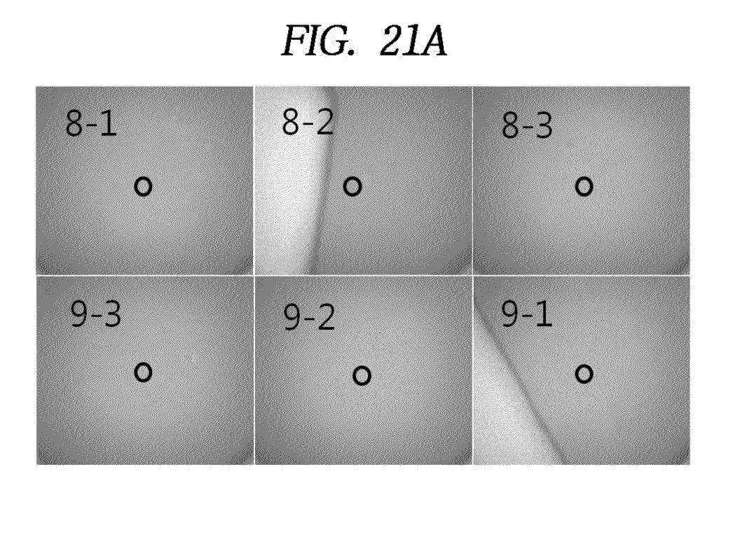

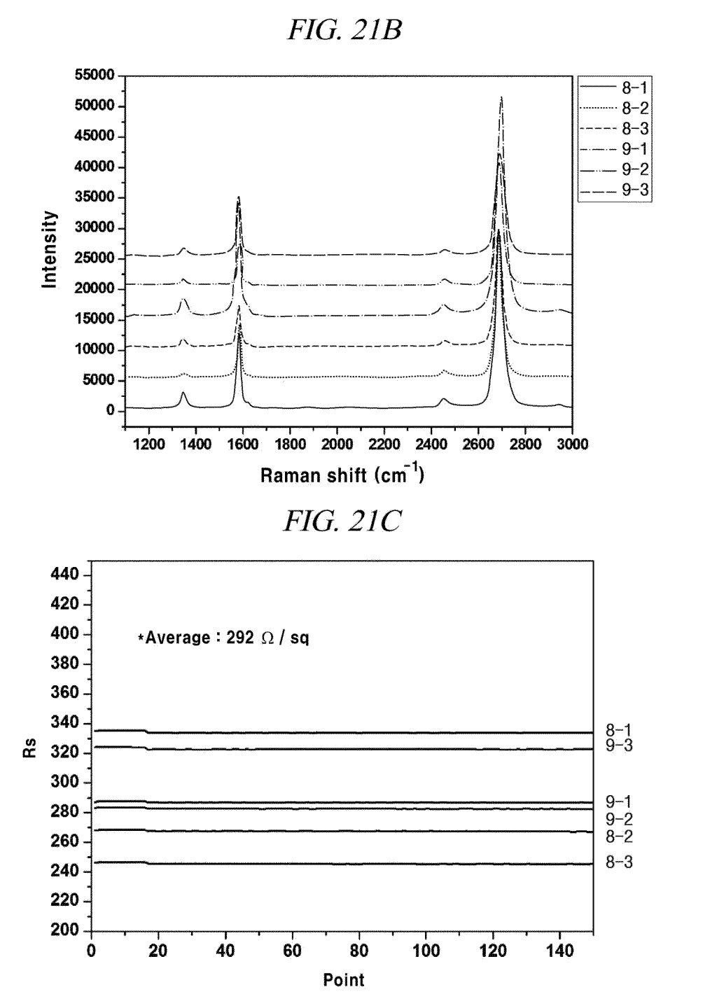

FIG. 21A to FIG. 21C provide an optical micrographs, Raman analysis graphs and sheet resistance graphs of graphene samples depending on the position of the sample, respectively, which were synthesized under the conditions of copper foil (8) and copper foil (9). As shown in FIG. 21A, in the present example, it was proved that high-quality graphenes could be synthesized under the conditions of copper foil (8) (8-1, 8-2 and 8-3 in FIG. 21A) and copper foil (9) (9-1, 9-2 and 9-3 in FIG. 21A) even if synthesized several times repeatedly. Further, as can be seen from FIG. 21B, the graphenes synthesized under the conditions of copper foil (8) (8-1, 8-2 and 8-3 in FIG. 21A) and copper foil (9) (9-1, 9-2 and 9-3 in FIG. 21A) according to the present example exhibited uniform monolayer graphene peaks. In addition, as depicted in FIG. 21C, sheet resistance values of the copper foils (8) (8-1, 8-2 and 8-3 in FIG. 21A) and the copper foils (9) (9-1, 9-2 and 9-3 in FIG. 21A) synthesized at the same date according to the present disclosure were in the range of from 250 Ω/sq to 330 Ω/sq, and an average of the samples was 292 Ω/sq (see FIG. 21C).

Analysis of UV-IR Transmittance of Graphene Transferred After Synthesized Using Near-Infrared Light

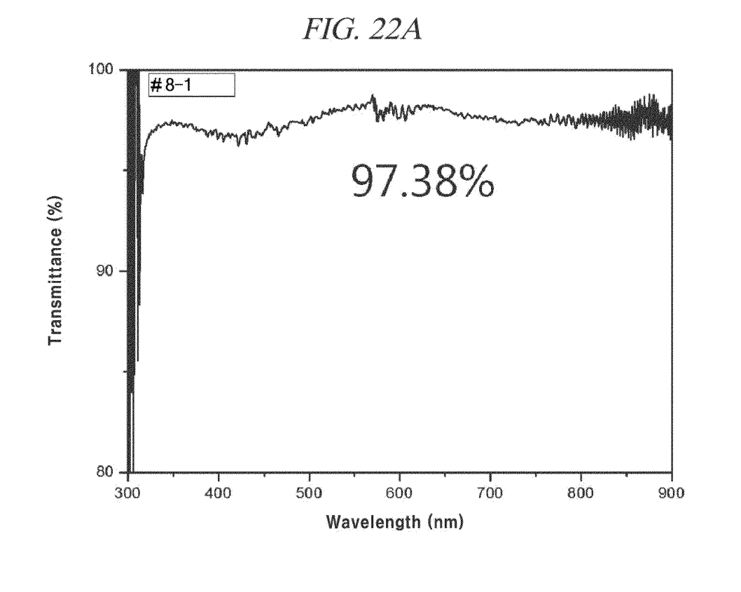

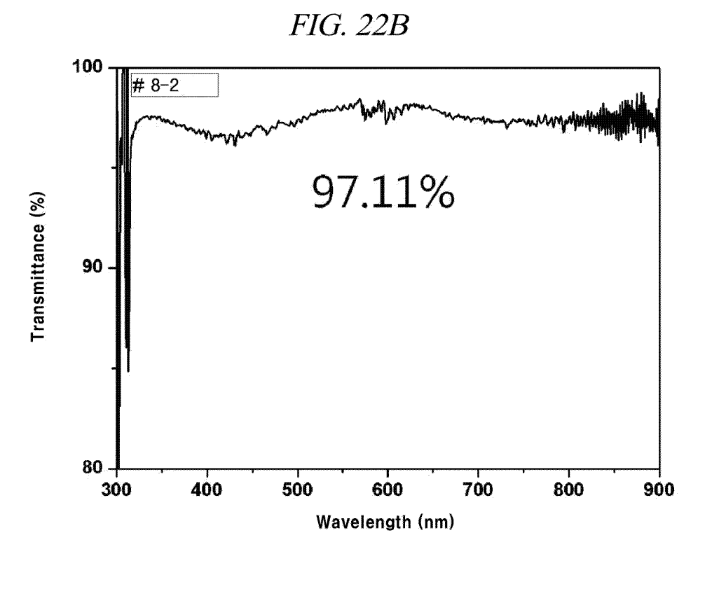

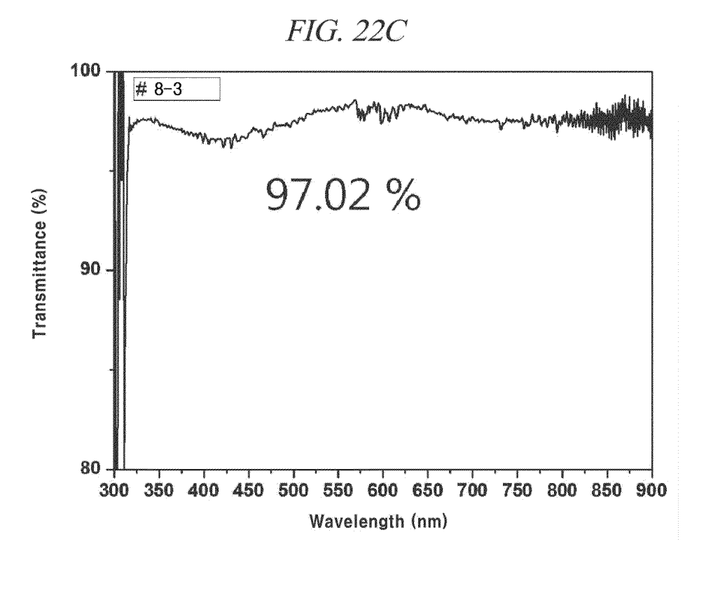

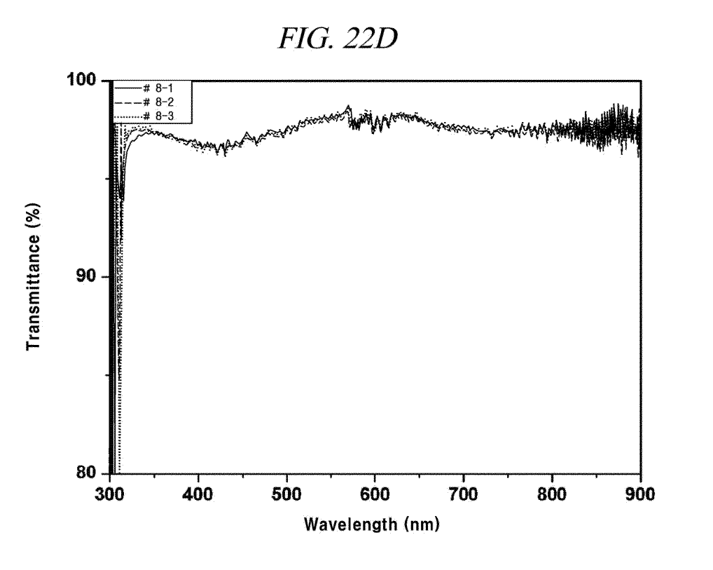

In the present example, a graphene synthesized using near-infrared light was transferred on a PET film, and a UV-IR transmittance was acquired. As can be seen from FIG. 22A to FIG. 22D, three samples prepared under the condition of copper foil (8) were measured, and they all exhibited high transmittance of about 97%. This result indicated that monolayer graphene was transferred to the PET film.

The above description of the illustrative embodiments is provided for the purpose of illustration, and it would be understood by those skilled in the art that various changes and modifications may be made without changing technical conception and essential features of the illustrative embodiments. Thus, it is clear that the above-described illustrative embodiments are illustrative in all aspects and do not limit the present disclosure. For example, each component described to be of a single type can be implemented in a distributed manner. Likewise, components described to be distributed can be implemented in a combined manner.

The scope of the inventive concept is defined by the following claims and their equivalents rather than by the detailed description of the illustrative embodiments. It shall be understood that all modifications and embodiments conceived from the meaning and scope of the claims and their equivalents are included in the scope of the inventive concept.

### EXPLANATION OF CODES

100: chamber

120: transparent window

140: gas supply unit

142: carbon source injector

144: hydrogen gas injector

146: argon gas injector

148: backup gas injector

160: vacuum pump

180: door

200: near-infrared light source

310: metal catalyst

330: metal catalyst supporting unit

We claim:

1. A method of preparing a graphene using near-infrared light, comprising:
loading a metal catalyst in a chamber containing a transparent window;
supplying a reactant gas containing a carbon source into the chamber; and
irradiating near-infrared (NIR) light from the outside of the chamber to the metal catalyst through the transparent window to generate heat from the metal catalyst, thereby reacting the matal catalyst with the carbon source to grow a graphene on a surface of the metal catalyst.

2. The method of claim 1,
wherein the near-infrared light has a wavelength in the range of from 700 nm to 1,500 nm.

3. The method of claim 1,
wherein the near-infrared light has a color temperature in the range of from 2,200 K to 3,500 K.

4. The method of claim 1,
wherein the metal catalyst includes a member selected from the group consisting of Ni, Co, Fe, Pt, Au, Al, Cr, Cu, Mg, Mn, Mo, Rh, Si, Ta, Ti, W, U, V, Zr, brass, bronze, stainless steel, Ge, and combinations thereof.

5. The method of claim 1,
wherein the metal catalyst includes a metal catalyst layer formed on a substrate.

6. The method of claim 1,
wherein the metal catalyst is formed on a substrate in a roll form.

7. The method of claim 1,
wherein the carbon source is in a gas phase or liquid phase.

8. The method of claim 1,
wherein the carbon source includes a member selected from the group consisting of carbon monoxide, carbon dioxide, methane, ethane, ethylene, ethanol, acetylene, propane, butane, butadiene, pentane, pentene, cyclopentadiene, hexane, cyclohexane, benzene, toluene, and combinations thereof.

9. The method of claim 1,
wherein one to twenty metal catalysts are loaded in the chamber.

10. The method of claim 1,
wherein the near-infrared light is irradiated to the metal catalyst form one to six directions to grow one to six graphenes on the metal catalyst simultaneously.

11. The method of claim 1,
wherein the transparent window is formed in at least one side of the chamber.

12. The method of claim 1,
wherein the transparent window includes quartz, sapphire, or glass.

13. An apparatus for preparing a graphene by using near-infrared light, comprising:
a chamber for accommodating a metal catalyst loaded therein;
a transparent window formed on at least one side of the chamber;
a reactant gas supply unit configured to supply a reactant gas containing a carbon source into the chamber; and
a near-infrared light source provided outside the chamber, and configured to irradiate near-infrared light into the chamber through the transparent window to allow the metal catalyst to generate heat.

14. The apparatus of claim 13,
wherein the transparent window includes quartz, sapphire, or glass.

15. The apparatus of claim 13,
wherein the near-infrared light source includes near-infrared heating module.

16. The apparatus of claim 13,
wherein the near-infrared light source is configured to irradiate near-infrared light of a wavelength in the range of from 700 nm to 1,500 nm.

17. The apparatus of claim 13,
wherein the number of the near-infrared light source is one or more.

18. The apparatus of claim 13,
wherein the metal catalyst includes a metal catalyst layer formed on a substrate.

19. The apparatus of claim 13,
wherein the metal catalyst is formed on a substrate in a roll form.

20. The apparatus of claim 13,
wherein the apparatus further comprises a metal catalyst supporting unit, provided in the chamber and configured to support the metal catalyst.
